(19) United States
(12) Patent Application Publication
(10) Pub. No.: US 2025/0334862 A1
(43) Pub. Date: Oct. 30, 2025

(54) ELECTRONIC APPARATUS

(71) Applicant: CANON KABUSHIKI KAISHA, Tokyo (JP)

(72) Inventors: HIDEKI SATO, Tokyo (JP); MASAYASU SHIGEMATSU, Tokyo (JP)

(21) Appl. No.: 19/088,123

(22) Filed: Mar. 24, 2025

(30) Foreign Application Priority Data
Apr. 30, 2024 (JP) 2024-073521

(51) Int. Cl. G03B 17/55; G03B 7/22; G03B 17/02; H05K 7/20

(52) U.S. Cl. CPC G03B 17/55; G03B 7/22; G03B 17/02; H05K 7/2039

(57) ABSTRACT

An electronic apparatus includes a heat radiating member to which heat generated by an electronic component is transferred, an exterior member covering the heat radiating member, and a positioning structure configured to position the heat radiating member relative to the exterior member so that the heat radiating member does not contact the exterior member.

### BACKGROUND

### Technical Field

The present disclosure relates to an electronic apparatus, such as an image pickup apparatus.

### Description of Related Art

The electronic apparatus is provided with a heat radiating structure that suppresses temperature rise caused by heat generated from the internal electronic components. U.S. Pat. No. 10,133,158 discloses a heat radiating structure that transfers heat generated from electronic components in an electronic apparatus (image pickup apparatus) to an exterior member via three heat radiating paths.

In the heat radiating structure disclosed in U.S. Pat. No. 10,133,158, the heat radiating member that is thermally connected to the electronic components is directly mechanically joined with the exterior member. Therefore, heat from the heat radiating member is directly transferred to the exterior member, and the temperature of the exterior member may rise excessively.

### SUMMARY

An electronic apparatus according to one aspect of the disclosure includes a heat radiating member to which heat generated by an electronic component is transferred, an exterior member covering the heat radiating member, and a positioning structure configured to position the heat radiating member relative to the exterior member so that the heat radiating member does not contact the exterior member.

Further features of various embodiments of the disclosure will become apparent from the following description of embodiments with reference to the attached drawings.

### BRIEF DESCRIPTION OF THE DRAWINGS

FIGS. 1A and 1B are perspective views illustrating the external appearance of a camera body according to this embodiment.

FIG. 2 is a block diagram illustrating the electrical configuration of the camera body according to this embodiment.

FIGS. 3A and 3B are an exploded view and a perspective view illustrating the internal structure of the camera body according to this embodiment.

FIGS. 4A and 4B are a sectional view and a partially enlarged view of the camera body according to this embodiment.

FIGS. 5A and 5B are another sectional view and another partially enlarged view of the camera body according to this embodiment.

FIG. 6 is yet another partially enlarged view of the camera body according to this embodiment.

### DETAILED DESCRIPTION

Referring now to the accompanying drawings, a description will be given of embodiments according to the disclosure.

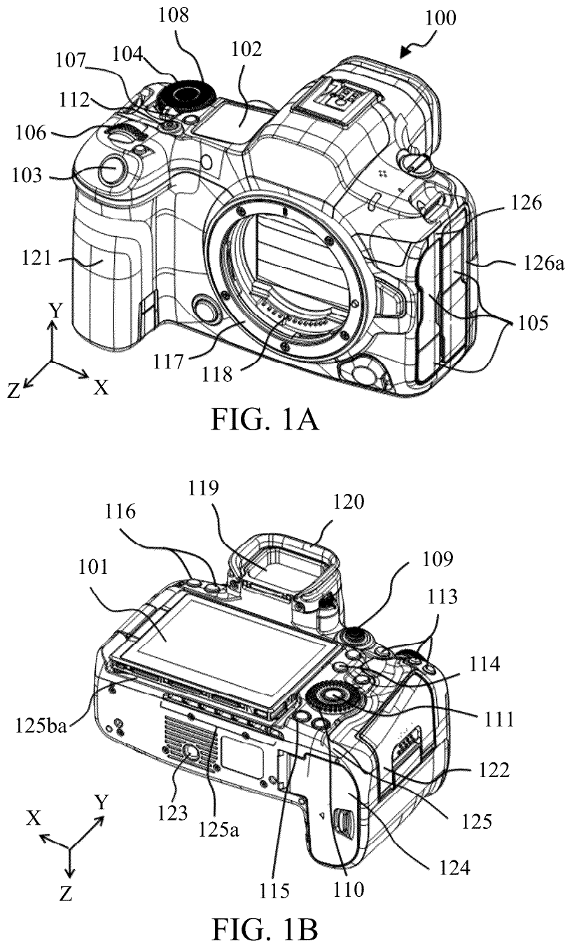

FIGS. 1A and 1B illustrate the appearance of a camera body (image pickup apparatus) 100 as an electronic apparatus according to this embodiment. FIG. 1A illustrates the camera body 100 viewed from the diagonal front side (object side), and FIG. 1B illustrates the camera body 100 viewed from the diagonal rear side. As illustrated in the figures, a width direction (left-right direction) of the camera body 100 is defined as an X(-axis) direction, a height direction (up-down direction) is defined as a Y(-axis) direction, and an optical axis direction (front-back direction) perpendicular to the imaging surface is defined as a Z(-axis) direction.

A rear display unit 101 is attached to the rear surface of the camera body 100 so that it can be opened, closed, and rotated relative to the camera body 100. The rear display unit 101 displays an image (e.g. a live-view image) generated by imaging and various information regarding imaging. The rear display unit 101 has a touch panel and can detect a user's touch operation on its display surface (operation surface).

The top surface of the camera body 100 is provided with a top display unit 102, a shutter button 103, a mode switch 104, a main electronic dial 106, a sub-electronic dial 108, and a moving image button 112. The top display unit 102 can display various settings regarding imaging, such as a shutter speed and an aperture value (F-number). The shutter button 103 is an operation member that the user operates in instructing imaging for recording. The mode switch 104 is an operation member that the user operates in switching between various imaging modes.

The main electronic dial 106 is an operation member that the user rotates to change settings regarding imaging. The power switch 107 is an operation member that the user operates in switching between the power-on and the power-off of the camera body 100. The sub-electronic dial 108 is an operation member that the user operates in moving a selection frame such as an autofocus (AF) frame and a distance measuring (focus detecting) frame, and in scrolling through images. The moving image button is an operation member that the user operates in instructing the start and stop of moving image recording.

Provided on the rear of the camera body 100 are a multi-controller 109, a rear electronic dial 110, a setting button 111, a button group A113, a button group B114, a button group C115, and a button group D116. The multi-controller 109 is configured to allow input by pressing the key top and tilting it up, down, left, right, and diagonally. By operating the multi-controller 109, the user can move the selection frame and select items in various menus. The rear electronic dial 110 is also an operation member operable by the user in moving the selection frame or forwarding images. The rear electronic dial 110 is located at a position where the user can easily operate it intuitively while an image is displayed on the rear display unit 101, and where the user can easily operate it while the user holds the camera body 100 in a vertical orientation.

The setting button 111 is provided at the center of the rear electronic dial 110. The setting button 111 is an operation member as a push button that the user operates when deciding on a selection item, etc. The button group A113 is an operation member regarding focus and exposure, and includes an AF start button, an auto-exposure (AE) lock button, and an AF frame selection button. In the imaging standby state, the user can press the button group A113 to start AF, change the AF frame, or fix the exposure.

The button group B114 includes an enlargement/reduction button, an information display button, and a quick setting button. In the live-view image display state (imaging mode), the user can operate the zoom in/out button to switch between the turning-on and turning-off of the enlargement in the live-view image. In the playback image display state (playback mode), the user can operate the zoom in/out button to switch between the turning-on and turning-off of the enlargement in the captured image being played. The user can operate the information display button to switch the display method of the information displayed on the rear display unit 101. In a case where the user operates the quick setting button, the user can transition the display on the rear display unit 101 to a screen for changing the settings regarding imaging.

The button group C115 includes a playback button and an erase button. In the playback button, the user can switch between the imaging mode and the playback mode. In a case where the playback button is operated in the imaging mode, the camera switches to the playback mode, and the latest captured image recorded on a recording medium (not illustrated) can be displayed on the rear display unit 101. In a case where a user selects a captured image in the playback mode, the user can erase the selected captured image by operating the erase button.

The button group D116 includes a menu button and a rating button. In a case where the user operates the menu button, a menu screen displaying settable items is displayed on the rear display unit 101. The user can intuitively select and set items by touching the menu screen displayed on the rear display unit 101 or by operating the multi-controller 109, rear electronic dial 110, and setting button 111. In a case where the user operates the rating button in the playback mode, the user can rate the playback image.

A mount unit 117 is provided on the front surface of the camera body 100, and an interchangeable lens unit (not illustrated) is attachable to and detachable from the mount unit 117. A communication terminal 118 provided inside the mount unit 117 is used for communication between the camera body 100 and the interchangeable lens unit.

A viewfinder 119 provided on the upper rear part of the camera body 100 is an electronic viewfinder (EVF) and allows the user to view a live-view image or the like by peeping through it. An eyepiece cover 120 is a rubber member that contacts the face around the eye of the user peeping through the viewfinder 119.

A grip unit 121 is a grip having a shape by which the user can easily hold the camera body 100 with his right hand. A card cover 122 is a cover that covers a media slot that stores a recording medium (not illustrated). The card cover 122 is provided on a part of the grip unit 121 where the palm of the user's hand comes into contact. A terminal cover 105 is a cover that protects a connector to which a connection cable extending from an external device can be connected. A tripod seat 123 is an attachment member that is used to attach an external accessory to the bottom surface of the camera body 100. A battery cover 124 is a cover for opening and closing a battery chamber that stores a battery (not illustrated).

A rear exterior member 125 is an exterior member that covers the rear and bottom of the camera body 100, and is made of metal, polycarbonate, or the like. The rear exterior member 125 has a body air-intake port 125a on its bottom surface, and a storage portion 125ba for storing the rear display unit 101 on its rear surface.

A side-surface exterior member 126 is an exterior member that forms the left side surface when the camera body 100 is viewed from the rear side, and is made of metal, polycarbonate, or the like. The side-surface exterior member 126 has a main body exhaust port 126a.

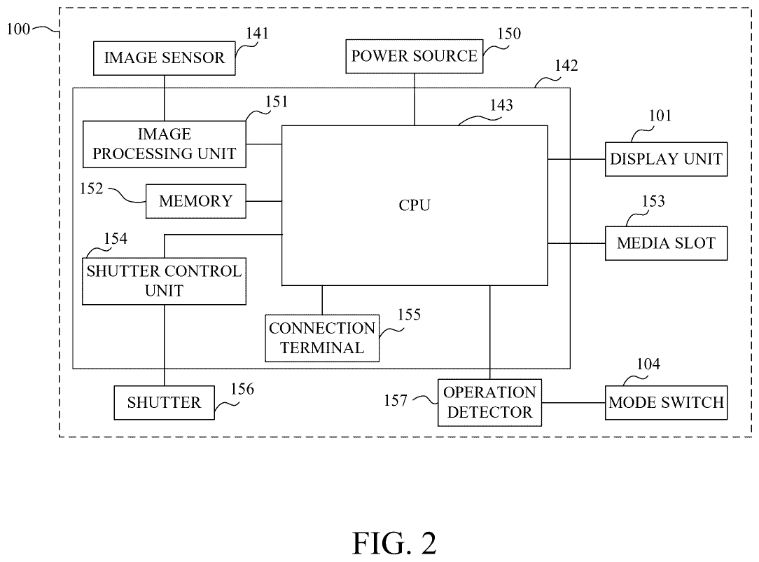

FIG. 2 illustrates the electrical configuration of the camera body 100. A Central Processing Unit (CPU) 143 is a computer that controls the overall operation of the camera body 100. Various electronic components, such as the CPU 143, which is one of the heat generating components, are mounted on a main circuit board 142. The main circuit board 142 is a printed wiring board (PWB). The CPU 143 controls the operation of the camera body 100 and performs the necessary calculations in accordance with the computer program loaded from the memory 152. A power supply 150 supplies power to each component in the camera body 100.

An image sensor 141 is a photoelectric conversion element such as a CCD sensor or a CMOS sensor, and converts an object image formed by an imaging optical system in the interchangeable lens unit into an imaging signal, which is an electrical signal. The imaging signal obtained by the image sensor 141 is converted into image data by an image processing unit 151. A shutter 156 is disposed in front of the image sensor 141. The shutter 156 controls the exposure time of the image sensor 141. The shutter control unit 154 controls the operation of the shutter 156 according to a command from the CPU 143.

An operation detector 157 detects that the mode switch 104, also illustrated in FIG. 1A, has been operated, and outputs an operation signal to the CPU 143. Thereby, the CPU 143 changes the settings such as the shutter speed and aperture value. The user can select a desired mode from among a plurality of moving image capturing modes by operating the mode switch 104.

The moving image capturing modes include a high-image-quality mode and a low-image-quality mode. In capturing a moving image in the high-image-quality mode, the load of processing performed by the image sensor 141 and the CPU 143 is large, so a heat amount generated by these electronic components and a heat amount generated by the recording medium as electronic components attached to the media slot 153 increase. When the heat amount generated increases and the temperature of the camera body 100 exceeds a permissible value, there is a risk of thermal runaway of the electronic components and a reduced lifespan of the camera body 100, so it is to reduce the continuous moving image capturing time. The CPU 143 detects the temperature of the exterior members such as the rear exterior member 125 using a temperature sensor, and when the detected temperature exceeds a predetermined temperature, the CPU 143 performs control to reduce the continuous moving image capturing time compared to when the temperature is below the predetermined temperature.

On the other hand, in capturing a moving image in the low-image-quality mode, a heat amount generated by the electronic components is smaller than that in the high-image-quality mode, so the continuous moving image capturing time can be increased. In continuous still-image shooting, when the temperature of an exterior member such as the rear exterior member 125 exceeds a predetermined temperature, the CPU 143 performs control to slow (reduce) the continuous still-image shooting speed compared to when the temperature is below the predetermined temperature. Thus, the camera body 100 has a function to restrict the operation of the camera body 100 according to the temperature of the exterior member.

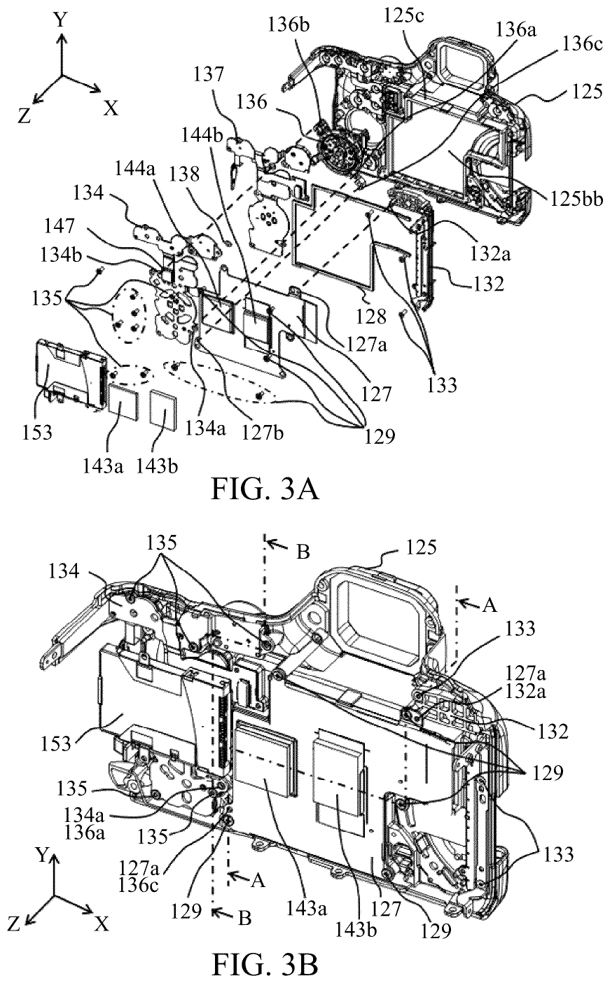

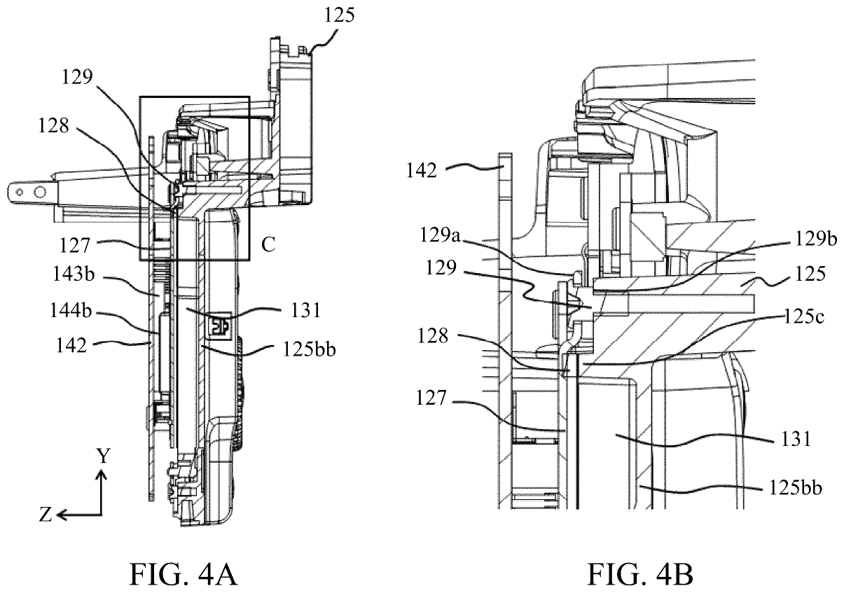

FIGS. 3A, 3B, 4A, and 4B illustrate the internal structure of the camera body 100. FIG. 3A illustrates an exploded view of the inside of the camera body 100 when viewed from the front in the Z direction. FIG. 3B illustrates the assembled state of the internal structure illustrated in FIG. 3A when viewed from the front. FIG. 4A illustrates a section of the internal structure illustrated in FIG. 3B taken along a line A-A. FIG. 4B illustrates an enlarged view of an area C in FIG. 4A.

The rear exterior member 125 has a storage-portion inner-surface 125bb, which is a rear surface of the storage portion 125ba illustrated in FIG. 1B, and a wall portion 125c that extends along the outer circumference of the storage-portion inner-surface 125bb and protrudes forward. A first sheet metal member 127 and a second sheet metal member 134, which are heat radiating members, are fixed to the rear exterior member 125 (wall portion 125c) by a method described below so that they are covered with the rear exterior member 125.

The first sheet metal member 127 is made of a metal such as aluminum that has high thermal conductivity and an outer shape that follows the wall portion 125c, and has hole portions 127a and 127b. Each of the hole portions 127a and 127b has an inner diameter that allows a protrusion portion 132a of a hinge fixing member 132 described below and a protrusion portion 136c of a base member 136 described below can be engaged.

A cushion member 128, which is an elastic member such as a sponge or felt and has a lower thermal conductivity than that of the first sheet metal member 127, is disposed between the wall portion 125c of the rear exterior member 125 and the first sheet metal member 127. The first sheet metal member 127 is positioned and fixed to the rear exterior member 125 by a method (positioning structure) described below using a plurality of (five in this embodiment) first fastening members 129. The first fastening members 129 are stepped screws, and are made of a steel material or the like having a lower thermal conductivity than that of the first sheet metal member 127.

The CPU 143 illustrated in FIG. 2 includes a first CPU 143a and a second CPU 143b. The first CPU 143a and the second CPU 143b are electronic components that generate different heat amounts. As illustrated in FIG. 4A, the first CPU 143a and the second CPU 143b are mounted on a surface on the first sheet metal member side of the main circuit board 142, which is omitted in FIGS. 3A and 3B.

A first heat transfer member 144a and a second heat transfer member 144b are disposed between the first sheet metal member 127 and the first CPU 143a, and between the first sheet metal member 127 and the second CPU 143b, respectively. The first heat transfer member 144a and the second heat transfer member 144b are members for transferring heat generated from the first CPU 143a and the second CPU 143b, respectively, to the first sheet metal member 127. In this embodiment, the first heat transfer member 144a is made of heat conductive rubber, and the second heat transfer member 144b is made of a graphite sheet. However, the first and second heat transfer members may be made of materials other than heat conductive rubber and graphite sheets.

The hinge fixing member 132 is fixed to the rear exterior member 125 by a plurality of (three in this embodiment) second fastening members 133. The hinge fixing member 132 has a hinge portion (not illustrated) that supports the opening/closing and rotation of the rear display unit 101, and has a shape that supports a button group D116 to be pressed. The hinge fixing member 132 is provided with a protrusion portion 132a that protrudes toward the front and is engaged with the hole portion 127a of the first sheet metal member 127 as described above. The hinge fixing member 132 is a resin member formed of resin, and has a lower thermal conductivity than that of the first sheet metal member 127.

The second sheet metal member 134 serving as a heat radiating member is fixed to the rear exterior member 125 by a method (fixing structure) described later using a plurality of (eight in this embodiment) third fastening members 135. The second sheet metal member 134 is formed of a metal such as aluminum, which has a high thermal conductivity, similarly to the first sheet metal member 127. The second sheet metal member 134 is used as a member for supporting the multi-controller 109, rear electronic dial 110, setting button 111, button group (A to C) 113, 114, and 115, etc. (collectively referred to as a grip-side rear-surface operation unit hereinafter), which are pressed or rotated by the user. The second sheet metal member 134 has holes 134a and 134b. The holes 134a and 134b have an inner diameter that allows protrusion portions 136a and 136b of the base member 136, which will be described later, to be engaged with the holes.

Arranged between the second sheet metal member 134 and the rear exterior member 125, in order from the rear side, are the base member 136, which is fixed to the rear exterior member 125 and supports the rear electronic dial 110, a flexible printed circuit (FPC) 137 on which the grip-side rear operation unit is mounted, and the sheet member 138. In this embodiment, the base member 136 is a resin member, and the sheet member 138 is a resin sheet such as a polyester film, both of which have a lower thermal conductivity than that of the second sheet metal member 134. However, the sheet member 138 may be formed from a resin material other than polyester.

The base member 136 has protrusion portions 136a, 136b, and 136c that protrude toward the front. As described above, the protrusion portions 136a and 136b are engaged with the holes 134a and 134b in the second sheet metal member 134, respectively, and the protrusion portion 136c is engaged with the hole portion 127b in the first sheet metal member 127.

Similarly to the first and second CPUs 143a and 143b, the media slot 153 is mounted on the second sheet metal member side of the main circuit board 142. The third heat transfer member 147 is disposed between the second sheet metal member 134 and the media slot 153. The third heat transfer member 147 is a member that transfers heat generated from a recording medium (not illustrated) attached to the media slot 153 to the second sheet metal member 134 via the media slot 153. In this embodiment, the third heat transfer member 147 is made from a graphite sheet. However, the third heat transfer member 147 may be formed from a material other than a graphite sheet.

A description will now be given of a method of assembling the internal structure including the first sheet metal member 127 and the second sheet metal member 134.

A description will now be given of a method of assembling the portion of the internal structure including the second sheet metal member 134. The Z direction is the assembly direction (first direction) of the first sheet metal member 127 and the second sheet metal member 134 with the rear exterior member 125, and the X direction and the Y direction are directions (second directions) orthogonal to the assembly direction. This embodiment has a positioning structure for the first sheet metal member 127 and the second sheet metal member 134 in the X and Y directions using the hinge fixing member 132 and the base member 136.

First, the base member 136 is positioned relative to the rear exterior member 125 in the X and Y directions.

Next, the FPC 137 and the sheet member 138 are adhered to the rear surface of the second sheet metal member 134. Then, the protrusion portions 136a and 136b of the base member 136 are engaged with the holes 134a and 134b in the second sheet metal member 134, respectively. Thereby, the second sheet metal member 134 is positioned in the X and Y directions relative to the rear exterior member 125 via the base member 136.

The second sheet metal member 134 is positioned and fixed in the Z direction relative to the rear exterior member 125 by the third fastening member 135. At this time, the base member 136 is also fixed to the rear exterior member 125 by the third fastening member 135.

A description will now be given of a method of assembling the portion of the internal structure including the first sheet metal member 127. First, the hinge fixing member 132 is positioned in the X and Y directions relative to the rear exterior member 125. Then, the hinge fixing member 132 is fixed to the rear exterior member 125 by the second fastening members 133.

Next, the cushion member 128 is adhered to the front-end surface of the wall portion 125c of the rear exterior member 125. The protrusion portion 132a of the hinge fixing member 132 and the protrusion portion 136c of the base member 136 are engaged with the hole portions 127a and 127b in the first sheet metal member 127, respectively. Thereby, the first sheet metal member 127 is positioned in the X and Y directions relative to the rear exterior member 125 via the hinge fixing member 132 and the base member 136. The first sheet metal member 127 is then positioned and fixed to the rear exterior member 125 in the Z direction using the first fastening member 129.

Thus, in this embodiment, the first sheet metal member 127 is positioned in the X and Y directions relative to the rear exterior member 125 via the hinge fixing member 132 and the base member 136, and the second sheet metal member 134 is positioned in the X and Y directions relative to the rear exterior member 125 via the base member 136. In other words, in the positioning structure in the X and Y directions, neither the first sheet metal member 127 nor the second sheet metal member 134 directly contacts the rear exterior member 125. Therefore, compared to when the first and second sheet metal members 127 and 134 are in direct contact with the rear exterior member 125 to perform positioning in the X and Y directions, this embodiment can suppress the transfer of heat from the first and second sheet metal members 127, 134 to the rear exterior member 125. Thereby, the temperature of the rear exterior member 125 can be prevented from excessively increasing due to the heat generated in the first and second CPUs 143a and 143b and the recording medium and transferred from the first and second sheet metal members 127 and 134 to the rear exterior member 125.

Referring now to FIGS. 4A and 4B, a description will be given of the positioning structure of the first sheet metal member 127 relative to the rear exterior member 125 in the Z direction in more detail. The first fastening member 129 and the cushion member 128 are members that are used for the positioning structure of the first sheet metal member 127 in the Z direction. The first fastening member 129, which is a stepped screw, is fixed to the rear exterior member 125 because its male threaded portion perforates through a hole formed in the first sheet metal member 127 and is screwed into a screw hole (female threaded) portion in the rear exterior member 125. In this state, a seat portion (rear surface of the head) 129a serving as a receiver of the first fastening member 129 contacts the first sheet metal member 127 in the Z direction, and a stepped surface 129b contacts the rear exterior member 125 in the Z direction. Thereby, the first fastening member 129 can be positioned in the Z direction relative to the rear exterior member 125.

At this time, the rear surface of the first sheet metal member 127 presses in the Z direction against the cushion member 128 adhered to the wall portion 125c of the rear exterior member 125. The thickness of the cushion member 128 in the Z direction before being pressed by the first sheet metal member 127 is greater than the thickness of the first sheet metal member 127 in the Z direction, and is also greater than the clearance in the Z direction between the front-end surface of the wall portion 125c and the back surface of the first sheet metal member 127. Therefore, in a case where the first sheet metal member 127 presses the cushion member 128, the cushion member 128 is compressed (elastically deformed). The first sheet metal member 127 is biased to the front in the Z direction by the repulsive force (elastic force) of the compressed cushion member 128, and comes into contact with the seat portion 129a of the first fastening member 129. Thus, the first sheet metal member 127 is positioned and fixed in the Z direction relative to the rear exterior member 125.

Although the positioning structure at one location of the positioning structures of the first sheet metal member 127 relative to the rear exterior member 125 by the first fastening members 129 at a plurality of locations has been described here, the first sheet metal member 127 is positioned and fixed at other locations by similar positioning structures.

The first sheet metal member 127 is positioned and fixed in the Z direction relative to the rear exterior member 125 by the first fastening members 129 and the cushion member 128 without directly contacting the rear exterior member 125. Therefore, compared to the case where the first sheet metal member 127 directly contacts the rear exterior member 125 and is fixed in the Z direction, the transfer of heat from the first sheet metal member 127 to the rear exterior member 125 can be suppressed. Thereby, the temperature of the rear exterior member 125 can be prevented from excessively increasing due to the heat generated by the first and second CPUs 143a and 143b and transferred from the first sheet metal member 127 to the rear exterior member 125.

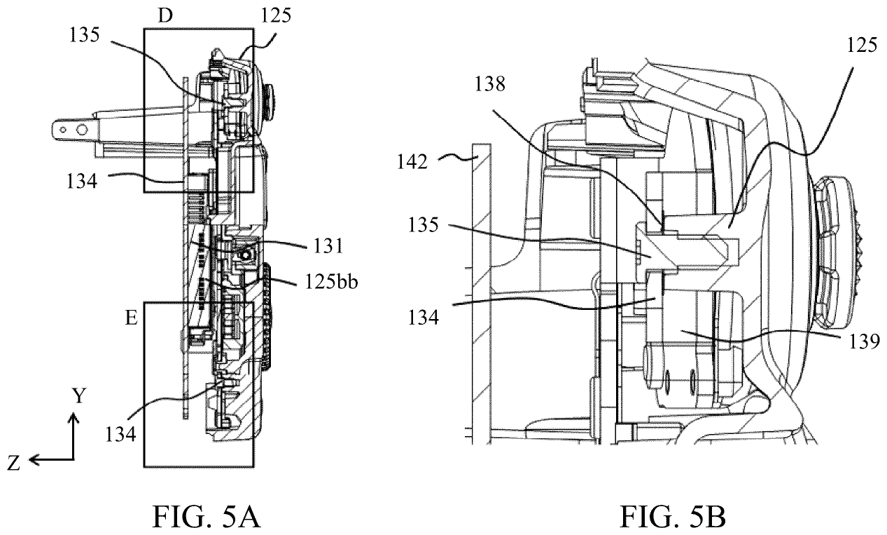

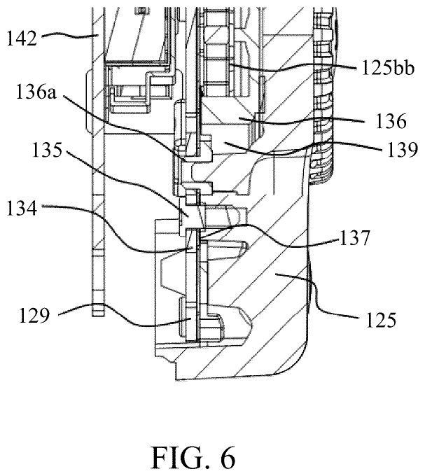

Referring now to FIGS. 5A, 5B, and 6, a description will be given of the fixing structure of the second sheet metal member 134 to the rear exterior member 125 in the Z direction in detail. FIG. 5A illustrates a section taken along a line B-B of the internal structure illustrated in FIG. 3B. FIG. 5B illustrates an enlarged view of an area D illustrated in FIG. 5A. FIG. 6 illustrates an enlarged view of an area E illustrated in FIG. 5A. The sheet member 138 and FPC 137 correspond to intermediate members.

The third fastening member 135 illustrated in FIG. 5B is fixed to the rear exterior member 125 because its male screw portion perforates through holes formed in the second sheet metal member 134 and the sheet member 138, and is screwed into a screw hole in the rear exterior member 125 so that the sheet member 138 contacts the rear exterior member 125 in the Z direction. The third fastening member 135 illustrated in FIG. 6 is fixed to the rear exterior member 125 because its male screw portion perforates through holes formed in the second sheet metal member 134 and the FPC 137 and is screwed into a screw hole in the rear exterior member 125 so that the FPC 137 contacts the rear exterior member 125 in the Z direction. The second sheet metal member 134 to which the sheet member 138 and the FPC 137 are adhered is positioned and fixed in the Z direction relative to the rear exterior member 125 by the third fastening member 135.

Although the fixing structure at two locations of the fixing structures of the second sheet metal member 134 relative to the rear exterior member 125 by the second fastening members 133 at a plurality of locations has been described here, the fixing structures at other locations also fix the second sheet metal member 134 by similar fixing structures.

The second sheet metal member 134 is fixed to the rear exterior member 125 in the Z direction via the third fastening member 135, the sheet member 138, and the FPC 137 without directly contacting the rear exterior member 125. Therefore, compared to the case where the second sheet metal member 134 is fixed in the Z direction by directly contacting the rear exterior member 125, the transfer of heat from the second sheet metal member 134 to the rear exterior member 125 can be suppressed. Thereby, the temperature of the rear exterior member 125 can be prevented from excessively increasing due to the heat generated by the recording media in the media slot 153 and transferred from the second sheet metal member 134 to the rear exterior member 125.

In this embodiment, as illustrated in FIG. 4B, first space 131 is formed between the first sheet metal member 127 and the storage-portion inner-surface 125bb of the rear exterior member 125. As illustrated in FIGS. 5B and 6, second space 139 is formed between the second sheet metal member 134 and the rear exterior member 125. Part of the heat transferred from the first and second CPUs 143a and 143b to the first sheet metal member 127 is transferred to the air in the first space 131, and Part of the heat transferred from the recording medium to the second sheet metal member 134 is transferred to the air in the second space 139. The air heated in the first and second spaces 131 and 139 is discharged to the outside of the camera body 100 by natural convection. A flow path may be formed that connects the body air-intake port 125a to the body exhaust port 126a through the first and second spaces 131 and 139. The air heated in the first and second spaces 131 and 139 may be exhausted to the outside of the camera body 100 through this flow path by using forced convection by an airflow generating unit such as a fan attached to the camera body 100.

This embodiment can avoid excessive temperature rise of the exterior member by suppressing heat transfer from the heat radiating members (127, 134) to the exterior member (125). This structure can suppress discomfort to a user touching the camera body, and a reduction in the continuous moving image capturing time and a reduction in the continuous shooting speed in continuous still-image shooting due to a rise in temperature.

This embodiment has discussed the positioning and fixing of the first and second sheet metal members 127 and 134 arranged so that the Z direction is the normal direction to the rear exterior member 125. However, the sheet metal members do not have to have the Z direction as the normal direction. In other words, a structure may be adopted in which the sheet metal members are arranged so that the X or Y direction is the normal direction, and they are positioned and fixed to the exterior members arranged on the side or upper part of the camera body via the intermediate member.

While the disclosure has described example embodiments, it is to be understood that the disclosure is not limited to the example embodiments. The scope of the following claims is to be accorded the broadest interpretation so as to encompass all such modifications and equivalent structures and functions.

According to the present disclosure, by suppressing the thermal conduction from the heat radiating sheet metal to the exterior member, an excessive temperature rise in the exterior member can be avoided.

This application claims priority to Japanese Patent Application No. 2024-073521, which was filed on Apr. 30, 2024, and which is hereby incorporated by reference herein in its entirety.

What is claimed is:

1. An electronic apparatus comprising:
a heat radiating member to which heat generated by an electronic component is transferred;
an exterior member covering the heat radiating member; and
a positioning structure configured to position the heat radiating member relative to the exterior member so that the heat radiating member does not contact the exterior member.

2. The electronic apparatus according to claim 1, wherein the positioning structure includes a member having a thermal conductivity lower than that of the heat radiating member.

3. The electronic apparatus according to claim 1, wherein the positioning structure includes a member having a fastening member fixed to the heat radiating member, and an elastic member elastically deformable between the heat radiating member and the exterior member, and
wherein in an assembly direction of the heat radiating member and the exterior member, the heat radiating member contacts a receiver provided to the fastening member under the elastic force of the elastic member at a position separated from the exterior member and is positioned at the position.

4. The electronic apparatus according to claim 1, wherein the positioning structure includes a resin member that is fixed to the exterior member and positions the heat radiating member relative to the exterior member in a direction orthogonal to an assembly direction of the heat radiating member and the exterior member.

5. The electronic apparatus according to claim 4, wherein the resin member is a member that supports an operation unit operable by a user.

6. The electronic apparatus according to claim 4, further comprising an intermediate member disposed between the heat radiating member and the exterior member so that the heat radiating member does not contact the exterior member.

7. The electronic apparatus according to claim 6, wherein the intermediate member is a member having a thermal conductivity lower than that of the heat radiating member.

8. The electronic apparatus according to claim 6, wherein the intermediate member is a resin sheet or a flexible printed circuit.

9. The electronic apparatus according to claim 1, wherein space is formed between the heat radiating member and the exterior member, and
wherein the electronic apparatus further comprises a structure configured to radiate the heat from the heat radiating member to air in the space and discharge the air to outside of the electronic apparatus.

10. The electronic apparatus according to claim 1, further comprising a control unit configured to restrict an operation of the electronic apparatus according to a temperature of the exterior member.

11. The electronic apparatus according to claim 10, wherein the electronic apparatus is an image pickup apparatus configured to image an object and generate an image, and
wherein the control unit reduces a continuous moving image capturing time or lowers a continuous still-image shooting speed according to the temperature.
